(19) United States
(12) Patent Application Publication
(10) Pub. No.: US 2013/0228214 A1
(43) Pub. Date: Sep. 5, 2013

(54) DYE-SENSITIZED SOLAR CELL ON NICKEL-COATED PAPER SUBSTRATE

(71) Applicants: Lei L. Kerr, Oxford, OH (US); Bo Wang, Oxford, OH (US)

(72) Inventors: Lei L. Kerr, Oxford, OH (US); Bo Wang, Oxford, OH (US)

(73) Assignee: MIAMI UNIVERSITY, Oxford, OH (US)

(21) Appl. No.: 13/784,030

(22) Filed: Mar. 4, 2013

Related U.S. Application Data
(60) Provisional application No. 61/605,940, filed on Mar. 2, 2012.

(51) Int. Cl. H01G 9/20; H01L 31/18

(52) U.S. Cl. CPC H01G 9/2095; H01G 9/204; H01L 31/1864
USPC 136/254; 428/464; 427/74; 438/85

(57) ABSTRACT

A conducting substrate made of a nickel coating on paper that can be used in a dye-sensitized solar cell (DSSC or DSC). Zinc oxide is the preferred wide-band semiconductor deposited as a nanoparticle layer on the nickel-coated paper to form a photoanode once a dye is deposited on the nanoparticles. A method of constructing the nickel-coated paper substrate is also contemplated.

### CROSS-REFERENCES TO RELATED APPLICATIONS

This application claims the benefit of U.S. Provisional Application No. 61/605,940 filed Mar. 2, 2012. This application is hereby incorporated by reference.

### STATEMENT REGARDING FEDERALLY-SPONSORED RESEARCH AND DEVELOPMENT

(Not Applicable)

### REFERENCE TO AN APPENDIX

(Not Applicable)

### BACKGROUND OF THE INVENTION

The invention relates generally to dye-sensitized solar cells (DSSCs), and more specifically to a new type of substrate used in a dye-sensitized solar cell and the method of constructing the substrate and the cell.

A conventional dye-sensitized solar cell is made of a porous layer of nanoparticles covered with a molecular dye that absorbs sunlight, like chlorophyll in plant leaves. The conventional dye-sensitized solar cell 1 has three primary parts as shown in FIG. 1. A transparent anode is made of a transparent conducting layer coating, such as the fluoride-doped tin dioxide (SnO₂:F, sometimes abbreviated “FTO”) layer 2a, deposited on the face of a typically glass plate 2. On this conductive layer a thin photoanode layer 5 is deposited. The photoanode layer 5 is made of a wide-bandgap semiconductor material in the form of nanoparticles, such as titanium dioxide (TiO₂, or titania). This nanoparticle photoanode layer 5 forms a highly porous matrix structure with extremely high surface area and good conductivity through the connected particles. In addition to titania, it is also known to use SnO₂ or ZnO as the photoanode layer 5.

The plate 2 is immersed in a mixture of a photosensitive ruthenium-polypyridine dye (also called molecular sensitizers). Soaking the film in the dye solution causes dye to be absorbed on the surfaces of the titania nanoparticles to enhance photon absorption.

A separate, FTO-coated glass plate 3 is coated with a catalyst material, typically platinum, as a thin layer 3a over the FTO coating. This forms a cathode for the cell 1. An iodide electrolyte 4 is spread over the thin platinum layer 3a and the two plates 2 and 3 are joined and sealed together as shown in cross section in FIG. 1 to prevent the electrolyte 4 sandwiched therebetween from leaking. The nanoparticle photoanode layer 5 is thereby in a hole-conducting liquid electrolyte solution, against which the platinum-based catalyst is also disposed.

Sunlight enters the cell and strikes the dye on the surface of the nanoparticle photoanode layer 5. Photons striking the dye with enough energy to be absorbed create an excited state of the dye. An electron can thus be “injected” directly into the conduction band of the nanoparticle photoanode layer 5 from the dye. Such electrons move to the clear anode layer 2a. Thus, when the dye absorbs light, the photoexcited electron is rapidly transferred to the conduction band of the semiconductor photoanode layer 5, which carries the electron to the anode.

The dye molecule that lost an electron takes an electron from iodide in the electrolyte at the nanoparticle layer 5, thereby oxidizing the iodide and forming triiodide (I₃⁻). This oxidation reaction occurs quickly compared to the time required for the electron injected into the conduction band of the photoanode layer 5 to recombine with the oxidized dye molecule, preventing this recombination reaction that would effectively short-circuit the solar cell. The triiodide recovers an electron by mechanically diffusing to the platinum layer 3a, where the cathode re-introduces the electrons to the cell 1 after the electrons flow through an external circuit. This is therefore a redox couple, consisting of iodide/triiodide (I⁻/I3⁻), that reduces the oxidized dye back to its neutral state and transports the positive charge to the platinized cathode. Iodide/triiodide is the most effective redox couple in current use. Organometallic complexes based on ruthenium provide the highest power-conversion efficiencies.

Thus, in a DSSC sunlight passes through the transparent anode into the dye layer where it can excite electrons that flow into the nanoparticles. The electrons flow toward the transparent anode where they are collected for powering a load. After flowing through the external circuit, they are re-introduced into the cell by the cathode, flowing into the electrolyte. The electrolyte then transports the electrons back to the dye molecules.

The dye molecules are nanometer sized, so in order to capture a significant amount of the light a nanomaterial is used as a scaffold to hold large numbers of the dye molecules in a 3-D matrix, increasing the number of molecules for any given surface area of cell. In existing designs, this scaffolding is provided by the semiconductor material of metal oxides.

Current dye-sensitized solar cell technology based on fluorine doped SnO₂ (FTO) coated glass substrates has problems with rigidity and weight. The need exists for a more flexible and lighter weight DSSC.

### BRIEF SUMMARY OF THE INVENTION

The invention contemplates coating a paper substrate with nickel or any nickel-containing alloy. In a preferred embodiment, the nickel-coated paper is used as a substrate in place of one of the FTO-coated glass plates in a dye-sensitized solar cell. This works particularly well in a dye-sensitized solar cell that uses ZnO as the photoanode layer. A method is also contemplated for coating the paper with nickel and for constructing the dye-sensitized solar cell using the nickel-coated paper. Of course, the nickel-coated paper can be used in any situation in which such a coating on paper is useful, such as any electronic component.

The results of the preferred embodiment of the present invention are significant, resulting in a dye sensitized solar cell with 1.21% efficiency (Voc=0.56 V, Jsc=6.70 mA/cm² and F.F.=0.33) using a paper substrate. Making DSSCs on paper opens the door for both photovoltaic and paper industries. The use of mature paper-making and paper-coating technologies greatly reduces cost of manufacture. Paper substrate based DSSCs not only offer the advantages of flexibility, portability and light weight but also provide the opportunity for feasible incorporation into textiles.

The invention contemplates a low temperature process to coat nickel uniformly on paper as a metal contact to form a substrate for the traditional FTO substrate. It is found that the control of metal oxide electrode morphology is critical to solar cell performance. Titania film has the tendency to crack on nickel-coated paper, which resulted in a shunt of the device and no solar cell efficiency was obtained. However, a zinc oxide (ZnO) film had good morphology tolerance on nickel-coated paper, and yielded good solar cell efficiency.

If solar cells can be made on paper substrates as the invention indicates, the photovoltaic industry can benefit greatly from the roll to roll mass production. Lamination is a common technology in the paper industry to protect paper against moisture. If DSSCs are made on paper, lamination technology can be adopted to improve the resistance of DSSCs against humidity.

Nickel is used as the metal contact by a simple low temperature chemical bath deposition method to replace the expensive FTO. Due to the morphology tolerance, ZnO is used and good cell efficiency is achieved.

In order to test the Ni corrosion resistance to electrolytes, Ni was immersed in an electrolyte solution for 2 hours and the transmittance of the electrolytes was taken by UV-vis spectrophotometer before and after immersion. Less transmittance change of electrolytes is an indication of better corrosion resistance. The transmittance of electrolytes did not change after nickel immersion. Thus, the corrosion resistance of nickel contacting the electrolyte used herein is suitable.

### BRIEF DESCRIPTION OF THE SEVERAL VIEWS OF THE DRAWINGS

FIG. 1 is a schematic illustration of a prior art dye-sensitized solar cell.

FIG. 2 is a schematic illustration of a preferred embodiment of the present solar cell using a conductive substrate constructed according to the invention.

FIG. 3 is a schematic illustration of a preferred conductive substrate, where the thicknesses and sizes of layers are shown for illustrative purposes and are not intended to reflect accurately the relative thicknesses of layers.

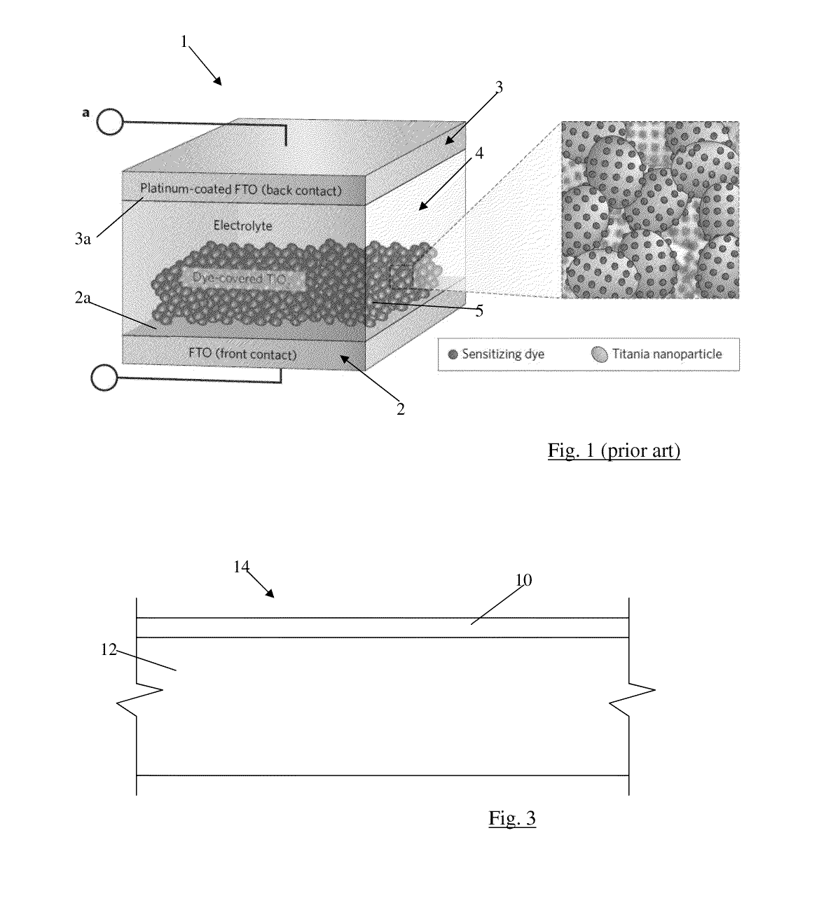

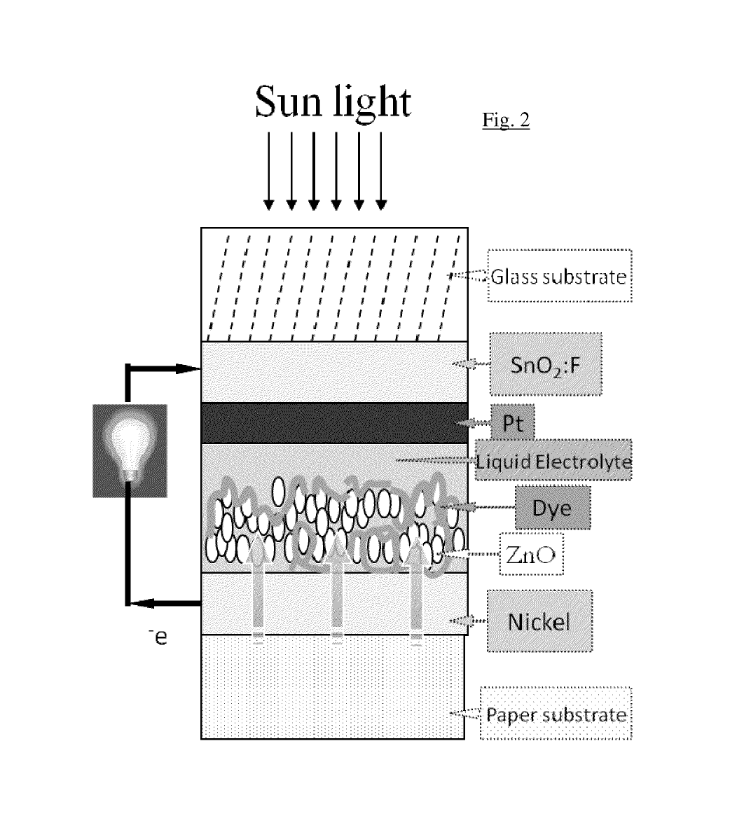

In describing the preferred embodiment of the invention which is illustrated in the drawings, specific terminology will be resorted to for the sake of clarity. However, it is not intended that the invention be limited to the specific term so selected and it is to be understood that each specific term includes all technical equivalents which operate in a similar manner to accomplish a similar purpose. For example, the word connected or terms similar thereto are often used. They are not limited to direct connection, but include connection through other elements where such connection is recognized as being equivalent by those skilled in the art.

### DETAILED DESCRIPTION OF THE INVENTION

U.S. Provisional patent application Ser. No. 61/605,940, which is the above-claimed priority application, is incorporated in this application by reference.

The dye-sensitized solar cells that are the subject of the present invention were constructed in a conventional manner except as noted herein. Therefore, except where described otherwise, the cell and each component thereof were formed in a conventional manner.

Box paper made by a Smart Papers, LLC of Hamilton, Ohio was used as the substrate due to its temperature, ethanol and electrolytes-soaking tolerances. Of course, a person having ordinary skill will understand from this disclosure that other papers are equally, more or less suitable for a given set of circumstances, and will understand that such papers can be substituted for the paper selected and described herein.

The first step in the process of constructing the conductive substrate is the deposition of nickel onto a paper substrate. This step was carried out using the following procedures, which are illustrative and are not the only manner of deposition contemplated, as will be understood by the person having ordinary skill from this disclosure. As noted above, a nickel coating 10 is applied to the paper 12 to form a conductive substrate 14 as shown schematically in FIG. 3. It is to be understood that a pure nickel coating is contemplated, as is a coating made of nickel with acceptable levels of impurities. Furthermore, nickel alloys that provide sufficient conductivity are also contemplated. Therefore, the term “nickel” is used herein to refer to pure nickel, nickel with acceptable impurities and nickel alloys.

The paper substrates were first immersed in a PbCl₂ solution (Solution II) for about 8 minutes, where PbCl₂ is used as a catalyst in this basic reaction. Following immersion in the PbCl₂ solution, the paper substrates were dipped into Solution I, which is a chemical bath reaction made of NiSO₄, Succinic acid (C₄H₆O₄), DL-malic acid (C₄H₆O₅) and Na₂HPO₂ in water. It will be understood that succinic acid and DL-malic acid are complexing agents, and thus are used to slow down the reaction speed and generate the fine particle nickel with uniform coating. Prior to immersion, the pH of Solution I was adjusted to 7.00-7.26 and the temperature was modified to about 70° C.

The immersion of the substrates in Solution I carried out the following reaction: 3NaH₂PO₂+3H₂O+NiSO₄→3NaH₂PO₃+H₂SO₄+2H₂+Ni. The nickel film was uniformly deposited at relatively low temperatures on the paper substrate by this reaction, as confirmed by energy dispersive spectroscopy (EDS) afterward. The sheet resistance of nickel-coated paper substrates measured by a conventional four point probe showed excellent conductivity of about 8 to 10 Siemens, which is similar to that of FTO glasses. Thus, a nickel layer 10 was deposited on the paper substrate 12 as desired, thereby forming a conductive substrate 14. The thickness of the nickel coating was in the range of a few microns, such as 1 to 2 microns, but this could be modified depending on the required parameters, as will be understood from the description herein by persons having ordinary skill

ZnO is an anistropic material with various morphologies, and is herein used in forming a photoanode layer on the nickel-coated paper substrate. The ZnO film deposition step was carried out using commercial ZnO nanopowder dispersed in a solution of acetic acid (1 vol %), ethanol (66 vol %) and water (33 vol %) in a weight ratio of 1:4. One exemplary

ZnO nanopowder is a Zinc Oxide Dispersion, product number 721077 sold by Sigma-Alderich, which has particles under 100 nm and average particle size less than 35 nm. This mixture formed a ZnO paste that was coated on a plurality of substantially identical paper substrates using a doctor blade method. In this conventional method, the paste is spread in the manner of a knife spreading butter on bread. Following deposition, the films were annealed in a paper drier at temperatures varying from 90 to 200° C. for 30 min. The ZnO films formed on the nickel-coated paper samples and annealed at temperature ranges of 90 to 200° C. showed no cracks in a scanning electron microscope (SEM) image, and had a thickness in the range of several microns, such as 5 to 10 microns. Of course, thinner and thicker coatings are considered within the range of the invention.

The dye used is N719 dye (chemical name cisdiisothiocyanato-bis(2,2′-bipyridyl-4,4′-dicarboxylato) ruthenium(II) bis(tetrabutylammonium)), and was applied to the ZnO layer in a conventional manner. The ZnO coated, nickel-coated paper substrate was soaked in 0.3 mM dye ethanol solution for 20 hours and removed. This completed the construction of the anode.

The counter electrode (cathode) of the DSSC was fabricated of platinum-coated FTO glass in a conventional manner. H₂PtCl₆ propanol solution (0.01 M) was prepared as precursor. One drop of H₂PtCl₆ solution was deposited on a piece of cleaned FTO glass with a pipette and a uniform liquid layer was formed on the FTO glass. The liquid layer was dried in air and the whole substrate was annealed at 400° C. for 30 minutes. The process was repeated three times for each sample.

The electrolyte was made with 0.1 M LiI, 0.05 M I₂, 0.6 M tetrabutylammonium iodide and 0.5 M tert-butylpyridine in dry acetonitrile. The anode and cathode were then assembled in a conventional manner with the electrolyte and tested for efficiency and other characteristics. An efficiency of 1.21% (Voc=0.56 V, Jsc=6.70 mA/cm² and F.F.=0.33) was obtained with this ZnO-based DSSC using the paper substrate. An AM 1.5 solar simulator (100 mW/cm²) was used as the illumination source and I-V curves were obtained with a digital source meter (Keithley 2400, Keithley Instruments). The measurement is calibrated with a Newport Si reference solar cell.

ZnO has thermal conductivity of about 100 W/m K. The thermal conductivity of Ni at room temperature is 91 W/m K. The temperature of 90° C. is the lowest temperature that ZnO can be formed via a chemical bath deposition using the bath solution of acetic acid (1 vol %), ethanol (66 vol %) and water (33 vol %) in a weight ratio of 1:4. Because a low temperature process is preferred when using paper substrates, 90° C. was preferred to make ZnO based DSSCs on paper substrates.

Although the temperatures and time periods stated herein are described with specificity, it will be understood by the person having ordinary skill that these can be modified while still retaining the benefits of the invention. Furthermore, although a nickel coating is described herein, it is possible that the so-called “nickel coating” or “nickel layer” is not pure nickel. Indeed, a pure coating is rare, and therefore it will be understood by a person of ordinary skill that a “nickel coating” and a “nickel layer” include impurities, and even minor alloying elements.

This detailed description in connection with the drawings is intended principally as a description of the presently preferred embodiments of the invention, and is not intended to represent the only form in which the present invention may be constructed or utilized. The description sets forth the designs, functions, means, and methods of implementing the invention in connection with the illustrated embodiments. It is to be understood, however, that the same or equivalent functions and features may be accomplished by different embodiments that are also intended to be encompassed within the spirit and scope of the invention and that various modifications may be adopted without departing from the invention or scope of the following claims.

1. A laminated substrate comprising:
(a) a paper layer; and
(b) a nickel layer attached to the paper layer.

2. The laminated substrate in accordance with claim 1, further comprising a zinc oxide layer attached to the nickel layer.

3. The laminated substrate in accordance with claim 2, further comprising a dye on at least the zinc oxide layer.

4. A solar cell comprising:
(a) a paper layer with a major surface;
(b) a nickel layer attached to at least the major surface of the paper layer; and
(c) a nanoparticle semiconductor layer attached to at least the nickel layer.

5. The solar cell in accordance with claim 4, wherein the nanoparticle semiconductor layer is made of zinc oxide.

6. A method of constructing a laminated substrate, the method comprising depositing a nickel layer on at least one surface of a paper substrate.

7. The method in accordance with claim 6, wherein the step of depositing a nickel layer comprises immersing the paper substrate in a liquid that includes at least NiSO₄, Succinic acid (C₄H₆O₄), DL-malic acid (C₄H₆O₅) and Na₂HPO₂ in water, the nickel layer adhering to said at least one surface of the paper substrate.

8. The method in accordance with claim 7, wherein the liquid into which the paper substrate is immersed has a pH in a range extending from about 7.00 to about 7.26.

9. The method in accordance with claim 8, wherein a temperature of the liquid is about 70° C.

10. The method in accordance with claim 7, wherein the paper substrate is immersed in a PbCl₂ solution before the paper substrate is immersed in the liquid.

11. The method in accordance with claim 10, wherein the paper substrate is immersed in the PbCl₂ solution for about eight minutes.

12. A method of constructing a laminated substrate, the method comprising:
(a) depositing a nickel layer on at least one surface of a paper substrate, the nickel layer adhering to said at least one surface of the paper substrate; and
(b) depositing a zinc oxide layer on at least a surface of the nickel layer that opposes the paper layer, the zinc oxide layer adhering to said surface of the nickel layer.

13. The method in accordance with claim 12, wherein the step of depositing the nickel layer comprises immersing the paper substrate in a liquid that includes at least NiSO₄, Succinic acid (C₄H₆O₄), DL-malic acid (C₄H₆O₅) and Na₂HPO₂ in water.

14. The method in accordance with claim 13, wherein the liquid into which the paper substrate is immersed has a pH in a range extending from about 7.00 to about 7.26, and a temperature of the liquid is about 70° C.

15. The method in accordance with claim 12, wherein the paper substrate is immersed in a PbCl₂ solution before the paper substrate is immersed in the liquid.

16. The method in accordance with claim 15, wherein the paper substrate is immersed in the PbCl₂ solution for about eight minutes.

17. The method in accordance with claim 12, wherein the step of depositing a zinc oxide layer comprises dispersing zinc oxide nanopowder in a solution comprising acetic acid, ethanol, and water to form a paste, and then applying the paste to the surface of the nickel layer.

18. The method in accordance with claim 17, wherein the solution includes about 1 volume percent acetic acid, about 66 volume percent ethanol and about 33 volume percent water, and the zinc oxide nanopowder is dispersed in the solution in a weight ratio of about 1 part nanopowder to about 4 parts solution.

19. The method in accordance with claim 18, further comprising annealing the film in an oven at a temperature in a range between about 90° C. and about 200° C. for about 30 minutes.
